(19) United States
(12) Patent Application Publication
(10) Pub. No.: US 2022/0302225 A1
(43) Pub. Date: Sep. 22, 2022

(54) DISPLAY PANEL AND MANUFACTURING METHOD THEREOF, AND DISPLAY DEVICE

(71) Applicant: BOE Technology Group Co., Ltd., Beijing (CN)

(72) Inventor: Dini XIE, Beijing (CN)

(21) Appl. No.: 17/405,974

(22) Filed: Aug. 18, 2021

(30) Foreign Application Priority Data
Mar. 22, 2021 (CN) 202110305856.X

(51) Int. Cl. H01L 27/32; H01L 51/52; H01L 51/56

(52) U.S. Cl. CPC H01L 27/3227; H01L 27/3246; H01L 51/5284; H01L 27/322; H01L 51/5237; H01L 51/56; H01L 2227/323

(57) ABSTRACT

A display panel includes a display substrate, and the display substrate includes: a base substrate, and a thin film transistor array and a light-emitting unit located on the base substrate; one or more photoelectric sensors located on a side of the light-emitting units away from the base substrate; one or more switching thin film transistors connected to the photoelectric sensors; and one or more collimating structures provided on a light incident side of the photoelectric sensors. And an orthographic projection of the photoelectric sensor on the base substrate is located within a gap between adjacent light-emitting units.

### CROSS-REFERENCE TO RELATED APPLICATIONS

This application claims priority to Chinese Patent Application No. 202110305856.X, filed in China on Mar. 22, 2021, the entire contents of which are incorporated herein by reference.

### TECHNICAL FIELD

The present disclosure relates to the technical field of display, in particular to a display panel and a manufacturing method thereof, and a display device.

### BACKGROUND

The photoelectric sensor can convert an optical signal into an electrical signal, and different light intensities can generate different current intensities, so that the photoelectric sensor can be used to realize a photographic function.

### SUMMARY

In a first aspect, embodiments of the present disclosure provide a display panel including: a display substrate, wherein the display substrate includes a base substrate, and one or more thin film transistor arrays and one or more light-emitting units located on the base substrate; one or more photoelectric sensors located on a side of the light-emitting units away from the base substrate; one or more switching thin film transistors connected to the photoelectric sensors; and one or more collimating structures provided on a light incident side of the photoelectric sensors. And an orthographic projection of the photoelectric sensor on the base substrate is located within a gap between adjacent light-emitting units.

According to one possible embodiment of the disclosure, the display panel further includes: a black matrix located between the light-emitting units and the photoelectric sensors. And the orthographic projection of the photoelectric sensor on the base substrate is located within an orthographic projection of the black matrix on the base substrate.

According to one possible embodiment of the disclosure, the display panel further includes: a pixel definition layer located on the base substrate. And the light-emitting unit is located in a pixel region defined by the pixel definition layer, the pixel definition layer is made of an opaque material, and the orthographic projection of the photoelectric sensor on the base substrate is located within an orthographic projection of the pixel definition layer on the base substrate.

According to one possible embodiment of the disclosure, the display panel further includes: a color filter layer located on a side of the collimating structure away from the photoelectric sensors.

According to one possible embodiment of the disclosure, the collimating structure includes: a light-shielding pattern and a micro-aperture located within the light-shielding pattern. And an orthographic projection of the micro-aperture on the base substrate is located within the orthographic projection of the photoelectric sensor on the base substrate.

According to one possible embodiment of the present disclosure, the photoelectric sensors correspond to sub-pixels of the display panel on a one-to-one basis; alternatively, each photoelectric sensor corresponds to a plurality of the sub-pixels.

According to one possible embodiment of the disclosure, the display panel further includes: an encapsulation layer covering the light-emitting unit. And the photoelectric sensor is provided on a side surface of the encapsulation layer away from the light-emitting unit.

According to one possible embodiment of the disclosure, the display panel further includes: an encapsulation cover plate arranged opposite to the display substrate. And the photoelectric sensor is provided on a side of the encapsulation cover plate facing the display substrate.

In a second aspect, embodiments of the present disclosure also provide a display device including a display panel, wherein the display device includes: a display substrate, wherein the display substrate includes a base substrate, and one or more thin film transistor arrays and one or more light-emitting units located on the base substrate; one or more photoelectric sensors located on a side of the light-emitting units away from the base substrate; one or more switching thin film transistors connected to the photoelectric sensors; and one or more collimating structures provided on a light incident side of the photoelectric sensors. And an orthographic projection of the photoelectric sensor on the base substrate is located within a gap between adjacent light-emitting units.

According to one possible embodiment of the disclosure, the display panel further includes: a black matrix located between the light-emitting units and the photoelectric sensors. And the orthographic projection of the photoelectric sensor on the base substrate is located within an orthographic projection of the black matrix on the base substrate.

According to one possible embodiment of the disclosure, the display panel further includes: a pixel definition layer located on the base substrate. And the light-emitting unit is located in a pixel region defined by the pixel definition layer, the pixel definition layer is made of an opaque material, and the orthographic projection of the photoelectric sensor on the base substrate is located within an orthographic projection of the pixel definition layer on the base substrate.

According to one possible embodiment of the disclosure, the display panel further includes: a color filter layer located on a side of the collimating structure away from the photoelectric sensors.

According to one possible embodiment of the disclosure, the collimating structure includes: a light-shielding pattern and a micro-aperture located within the light-shielding pattern. And an orthographic projection of the micro-aperture on the base substrate is located within the orthographic projection of the photoelectric sensor on the base substrate.

According to one possible embodiment of the present disclosure, the photoelectric sensors correspond to sub-pixels of the display panel on a one-to-one basis; alternatively, each photoelectric sensor corresponds to a plurality of the sub-pixels.

According to one possible embodiment of the disclosure, the display panel further includes: an encapsulation layer covering the light-emitting unit. And the photoelectric sensor is provided on a side surface of the encapsulation layer away from the light-emitting unit.

According to one possible embodiment of the disclosure, the display panel further includes: an encapsulation cover plate arranged opposite to the display substrate. And the photoelectric sensor is provided on a side of the encapsulation cover plate facing the display substrate.

In a third aspect, the embodiments of the present disclosure also provide a manufacturing method of a display panel. And the display panel includes a display substrate, the display substrate includes one or more thin film transistor arrays and one or more light-emitting units which are located on a base substrate, and the manufacturing method includes: forming one or more photoelectric sensors and one or more switching thin film transistors connected to the photoelectric sensors on a side of the light-emitting unit away from the base substrate; and forming one or more collimating structures on a light incident side of the photoelectric sensors. And an orthographic projection of the photoelectric sensor on the base substrate is located within a gap between adjacent light-emitting units.

According to one possible embodiment of the disclosure, the manufacturing method further includes: forming a black matrix between the light-emitting units and the photoelectric sensors. And the orthographic projection of the photoelectric sensor on the base substrate is located within an orthographic projection of the black matrix on the base substrate.

According to one possible embodiment of the disclosure, the manufacturing method further includes: forming a pixel definition layer using an opaque material on the base substrate. And the light-emitting unit is located within a pixel region defined by the pixel definition layer, and the orthographic projection of the photoelectric sensor on the base substrate is located in an orthographic projection of the pixel definition layer on the base substrate.

According to one possible embodiment of the disclosure, the manufacturing method further includes: forming a color filter layer on a side of the collimating structure away from the photoelectric sensor.

### BRIEF DESCRIPTION OF THE DRAWINGS

In order to more clearly explain the embodiments of the present disclosure or the technical solutions in the related art, a brief description will be given below with reference to the accompanying drawings to be used in the description of the embodiments, and it is obvious that the drawings in the description below are only some embodiments of the present disclosure, and other drawings can be obtained from these drawings by a person skilled in the art without involving any inventive effort.

FIG. 1 is a first schematic view illustrating a structure of a display panel according to an embodiment of the present disclosure;

FIG. 2 is a second schematic view illustrating a structure of a display panel according to an embodiment of the present disclosure;

FIG. 3 is a first schematic view of an exemplary light entering a photoelectric sensor;

FIG. 4 is a second schematic view of an exemplary light entering a photoelectric sensor;

FIG. 5 is a first schematic view of a photoelectric sensor array according to an embodiment of the present disclosure; and

FIG. 6 is a second schematic view of a photoelectric sensor array according to an embodiment of the present disclosure.

### DETAILED DESCRIPTION

In order that the technical problems to be solved by the embodiments of the present disclosure, technical solutions, and advantages can be more clearly understood, a detailed description will be given below with reference to the accompanying drawings and specific embodiments.

Integrating a photoelectric sensor array in a screen can realize a camera function, and a color filter of three primary colors of red, green and blue can also be arranged on the light incident side of the photoelectric sensor to realize the sensing function of the photoelectric sensor for different light intensities of different colors. However, the lights need to be converged before they enter the photoelectric sensor, otherwise the acquired image will be a blurred image.

Embodiments of the present disclosure provide a display panel, a manufacturing method thereof, and a display device capable of realizing a display substrate integrated with camera function and ensuring photographic quality.

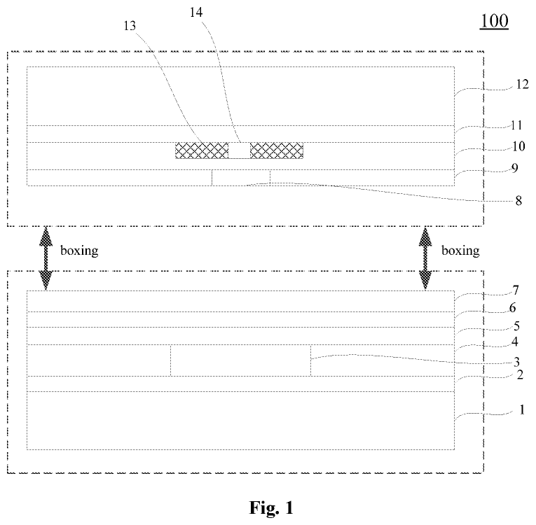

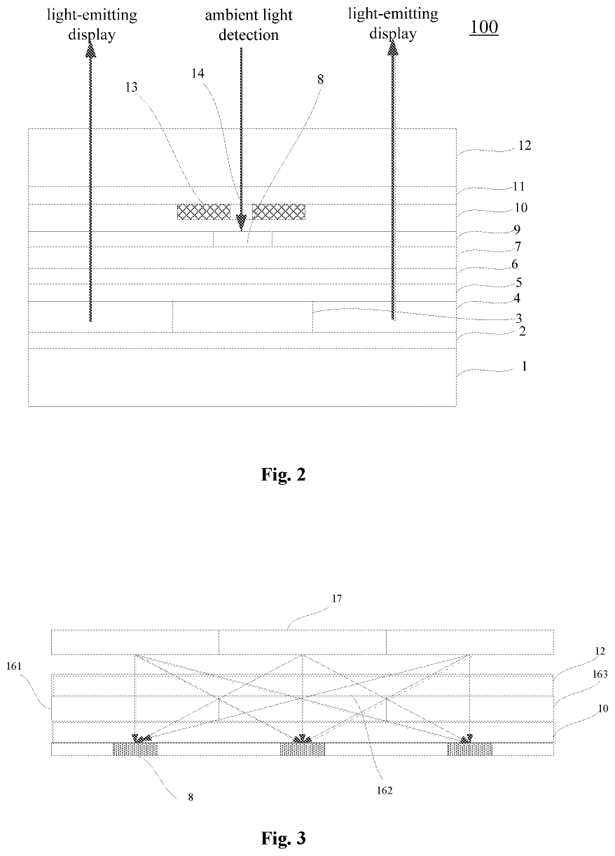

An embodiment of the present disclosure provides a display panel 100, as shown in FIGS. 1 and 2, including a display substrate. Specifically the display substrate includes one or more thin film transistor arrays 2 and one or more light-emitting units (not shown) which are located on a base substrate 1, and the display panel 100 further includes: one or more photoelectric sensors 8 located on a side of the light-emitting unit away from the base substrate 1; one or more switching thin film transistors 9 connected to the photoelectric sensors 8; one or more collimating structures 13 provided on the light incident side of the photoelectric sensors 8. Specifically the orthographic projection of the photoelectric sensor 8 on the base substrate 1 is located within a gap between adjacent light-emitting units.

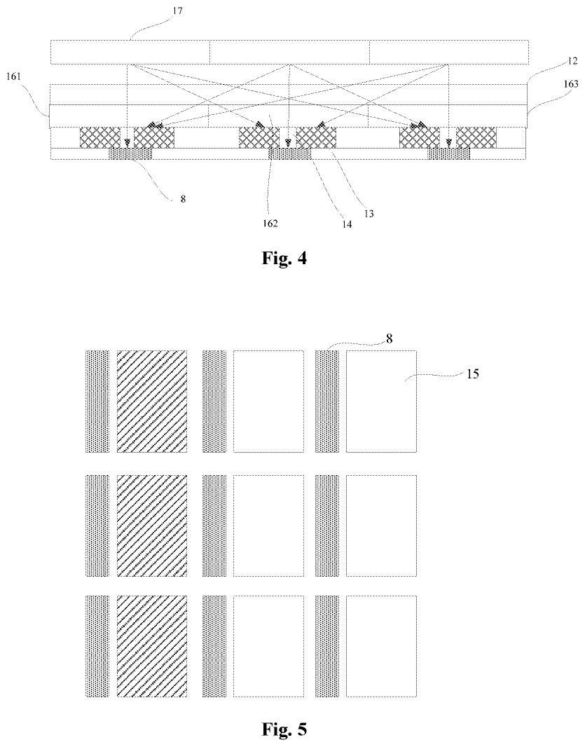

When a color or black-and-white picture in front of the display panel 100 is subjected to camera shooting and photographing with a photo sensor array, as shown in FIG. 3, when the photoelectric sensors 8 acquire an image of the color picture 17, the light information detected by each photoelectric sensor 8 is a superposition of the light information in a certain area nearby, thereby causing the acquired image to be a blurred image. Therefore, it is necessary to concentrate the lights, and if a liquid crystal lens is provided in front of the photoelectric sensor to achieve the light concentration function, it is difficult to achieve and difficult to mass produce. In this embodiment, as shown in FIG. 4, a collimating structure 13 is provided on the light incident side of the photoelectric sensor 8, and external light enters the photoelectric sensor 8 after passing through the collimating structure 13. Therefore, by providing the collimating structure 13 on the light incident side, each photoelectric sensor 8 can only detect the light information directly in front of it without being disturbed by the nearby light as much as possible, thereby enabling the photoelectric sensor array to capture a relatively clear image and improving the photographic quality. Accordingly, the solution of the present embodiment has a lower implementation cost and is easier to achieve mass production.

Specifically, as one non-limiting example, as shown in FIGS. 1 and 2, the collimating structure 13 includes a light-shielding pattern (i.e. an opaque or semi-transparent material disposed around the perimeter of the micro-aperture 14 shown in FIGS. 1 and 2) and a micro-aperture 14 provided in the light-shielding pattern. For example, the micro-aperture 14 is a long and straight aperture. As shown in FIGS. 1 and 2, the orthographic projection of the micro-aperture 14 on the base substrate 1 is located within the orthographic projection of the photoelectric sensor 8 on the base substrate 1. Accordingly, through the micro-aperture 14, the photoelectric sensor 8 will only detect light information directly in front of it and will not be disturbed by nearby light.

In this embodiment, each collimating structure 13 may include one micro-aperture 14 or a plurality of micro-apertures 14. When the collimating structure 13 includes a plurality of micro-apertures 14, the orthographic projections of the plurality of micro-apertures 14 on the base substrate 1 are all located within the orthographic projections of the corresponding photoelectric sensors 8 on the base substrate 1, so as to ensure that the light transmitted by the micro-apertures 14 is not transmitted to other areas.

Here, although the cross-sectional shape of the micro-apertures 14 shown in FIGS. 1 and 2 in the direction perpendicular to the plane of the base substrate 1 is rectangular, it will be understood by those skilled in the art that the cross-sectional shape may be provided in an inverted trapezoidal shape or other suitable shape according to actual needs, and the embodiments of the present disclosure are not limited thereto.

Accordingly, in order to avoid the influence of the light-shielding pattern on the display of the display panel 100, the collimating structure 13 is arranged between adjacent pixel areas so as not to block the light emitted from the pixel areas.

In this embodiment, as a non-limiting example, the photoelectric sensor 8 may employ a photodiode, for example.

In some embodiments, as shown in FIGS. 1 and 2, the display panel 100 further includes, for example: a black matrix 3 located between the light-emitting unit (not shown) and the photoelectric sensor 8. And the orthographic projection of the photoelectric sensor 8 on the base substrate is located within an orthographic projection of the black matrix 3 on the base substrate 1.

When the display panel 100 is operated, the light-emitting unit emits light, and if light of the light-emitting unit is received by the photoelectric sensor 8, the operation of the photoelectric sensor is disturbed, adversely affecting the imaging quality of the photoelectric sensor 8. In order to ensure the imaging quality, the present embodiment provides a black matrix 3 between the light-emitting unit (not shown) and the photoelectric sensor 8, the black matrix 3 being able to block the light emitted by the light-emitting unit (not shown), from interfering with the imaging of the photoelectric sensor 8. As shown in FIGS. 1 and 2, the light-emitting display of the display panel 100 and the ambient light detection of the photoelectric sensor 8 do not interfere with each other.

In this embodiment, the black matrix 3 can be formed on the display substrate through a special patterning process, and the insulating film layer of the display substrate can also be made of an opaque material or a semi-transparent material, and the opaque insulating film layer of the display substrate can be multiplexed as the black matrix.

In some embodiments, the display panel 100 further includes, for example: a pixel definition layer (not shown) located on the base substrate. Specifically, the light-emitting unit is located within a pixel region defined by the pixel definition layer, and the orthographic projection of the photoelectric sensor on the base substrate is located in an orthographic projection of the pixel definition layer on the base substrate. In this way, the photoelectric sensor is arranged between the adjacent pixel areas so as to be offset from the pixel areas, whereby the aperture ratio of the display panel 100 can be not affected.

The pixel definition layer may be made of a light-transmitting material or may be made of an opaque material. If the pixel definition layer is made of an opaque material, the pixel definition layer can be multiplexed into a black matrix, so that the black matrix does not need to be made on the display substrate through a special patterning process, and the structure and the manufacturing process of the display substrate can be greatly simplified.

In some embodiments, as shown in FIGS. 1 and 2, the display panel 100 further includes, for example: a color filter layer 11 located on a side of the collimating structure 13 away from the photoelectric sensor 8. In this way, imaging of a color image can be achieved. The color filter layer 11 and the photoelectric sensor 8 can both be provided on the display substrate; they may also be provided on the opposite substrate of the display substrate, such as on the encapsulation cover plate. It is also possible that the color filter layer 11 is provided on the encapsulation cover plate, and the photoelectric sensor 8 is provided on the display substrate.

The color filter layer 11 includes, for example, a plurality of filtering units of different colors. As shown in FIG. 4, the color filter layer 11 may include, for example, a first filtering unit 161, a second filtering unit 162, and a third filtering unit 163.

In this embodiment, the photoelectric sensors 8 are arranged in an array on the display panel 100, and can uniformly receive external light to realize imaging. Of course, it will be understood by those skilled in the art that the photoelectric sensors 8 may be arranged in a non-array manner on the display panel 100 as long as it is sufficient to uniformly receive external light for the purpose of imaging.

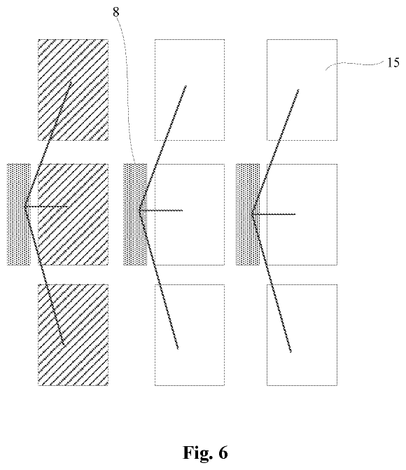

In some embodiments, as shown in FIG. 5, the photoelectric sensors 8 correspond to the sub-pixels 15 of the display panel 100 on a one-to-one basis, and the photoelectric sensors 8 are located between two adjacent sub-pixels 15 in the same row. Thus, the display panel 100 includes a sufficient number of photoelectric sensors 8, and the resolution of the image obtained by camera shooting is high, so that the imaging quality can be further ensured.

In some embodiments, it is also possible that each photo-sensor 8 corresponds to a plurality of the sub-pixels 15, as shown in FIG. 6, one photoelectric sensor 8 may be provided for every three sub-pixels 15 per column, or one photoelectric sensor 8 may be provided for more sub-pixels 15. Thus, the number of photoelectric sensors 8 is small, the cost of the display panel 100 can be reduced, and the influence on the aperture ratio of the display panel 100 is small.

In some embodiments, a display panel includes a display substrate. And the display substrate includes a thin film transistor array and a light-emitting unit on a base substrate, and the display panel further includes: an encapsulation layer (not shown) covering the light-emitting unit, the photoelectric sensor being provided on a side surface of the encapsulation layer away from the light-emitting unit. The switching thin film transistor connected to the photoelectric sensor may also be provided on the side surface of the encapsulation layer away from the light-emitting unit; the collimating structure may be provided on the side of the photoelectric sensor away from the base substrate; and the color filter layer may be located at a side of the collimating structure away from the base substrate. In this embodiment, a flexible display panel can also be realized when the base substrate is a flexible substrate.

In some embodiments, as shown in FIGS. 1 and 2, the display panel 100 includes, for example, a base substrate 1, a thin film transistor array 2 located on the base substrate 1, a black matrix 3, a light-emitting layer 4, a cathode 5, an encapsulation layer 6 and an optical glue layer 7. The display panel 100 further includes, for example: an encapsulation cover plate arranged opposite to the display substrate. And the encapsulation cover plate includes a base substrate 12, a color filter layer 11 provided on the base substrate 12, a collimating structure 13 located on the side of the color filter layer 11 away from the base substrate 12, a flat layer 10, a photoelectric sensor 8 located on the side of the flat layer 10 away from the collimating structure 13, and a switching thin film diode 9 connected to the photoelectric sensor 8. Specifically, after aligning the encapsulation cover plate and the display substrate to form a box, the encapsulation cover plate and the display substrate are combined together via the optical glue layer 7, and the photoelectric sensor 8 is located on the side of the encapsulation cover plate facing the display substrate.

When the display panel 100 is operated, the operation state of the photoelectric sensor can be controlled via the switching thin film transistor 9. When it is necessary to perform camera shooting, the switching thin film transistor 9 is turned on, and the photoelectric sensor 8 senses that an electric signal generated by external light is transmitted to a relevant circuit to perform imaging. When the camera shooting is not required, the switching thin film transistor 9 is turned off, and the photoelectric sensor 8 senses that the electric signal generated by the external light will not be transmitted to the relevant circuit. With the technical solution of the present embodiment, the under-screen photographic function can be realized, the function of the display panel 100 can be versatile, and the product competitiveness can be improved.

Embodiments of the present disclosure also provide a display device which includes the display panel 100 described above. The display device includes, but is not limited to: a radio frequency (RF) unit, a network module, an audio output unit, an input unit, a sensor, a display unit, a user input unit, an interface unit, a memory, a processor, and a power supply, etc. It will be appreciated by those skilled in the art that the configuration of the display device described above is not intended to be limiting and that the display device may include more or fewer of the components described above, or some combinations of the components, or different arrangements of the components. In embodiments of the present disclosure, display devices include, but are not limited to, displays, mobile phones, tablet computers, televisions, wearable electronics, navigation display apparatus, and the like.

The display device provided by the embodiments of the present disclosure is electroluminescent display device, and the electroluminescent display device can be Organic Light-Emitting Diode Display (OLED) and Quantum Dot Light Emitting Diodes (QLED). Taking the organic electroluminescent display device as an example, the organic electroluminescent display device can be one of PMOLED (Passive Matrix OLED) and AMOLED (Active Matrix OLED).

The display panel 100 includes a display substrate and an encapsulation layer for encapsulating the display substrate. Here, the encapsulation layer may be an encapsulation film; it may also be an encapsulation cover plate. In the case where the encapsulation layer is an encapsulation film, the number of layers of the encapsulation film included by the encapsulation layer is not limited, and the encapsulation layer may include one layer of the encapsulation film, or the encapsulation layer may include two or more layers of the encapsulation film arranged on top of each other. In some embodiments, the encapsulation layer includes three layers of the encapsulation film arranged on top of each other.

In the case where the encapsulation layer includes three layers of the encapsulation film arranged on top of each other, optionally, the material of the encapsulation film located at the intermediate layer is an organic material, and the material of the encapsulation films located at the two sides is an inorganic material.

Here, the organic material is not limited, and the organic material may be, for example, polymethyl methacrylate (PMMA). The inorganic material is not limited, and exemplarily the inorganic material may be one or more of SiNx (silicon nitride), SiOx (silicon oxide), or SiOxNy (silicon oxynitride).

On this basis, Ink Jet Printer (IJP) can be used to fabricate the encapsulation film located on the intermediate layer. In addition, Chemical Vapor Deposition (CVD) can be used to fabricate the encapsulation films on both sides.

The display substrate provided in the embodiments of the present disclosure may be a top emission type, in which case the anode is in an opaque state and the cathode is in a light-transmitting state. The display substrate may also be of an bottom emission type, in which case the anode is in a light-transmitting state and the cathode is in an opaque state. The display substrate may of course also be of a dual emission type, in which case both the anode and the cathode are in a light-transmitting state.

In some embodiments, the organic functional layer includes a light-emitting layer. In further embodiments, the organic functional layer includes, in addition to the light-emitting layer, for example, one or more of an election transporting layer (ETL), an election injection layer (EIL), a hole transporting layer (HTL), and a hole injection layer (HIL).

With reference to FIGS. 1 and 2, an embodiment of the present disclosure also provides a manufacturing method of a display panel 100, wherein the display panel 100 includes a display substrate, the display substrate includes a thin film transistor array 2 and a light-emitting unit which are located on a base substrate, and the manufacturing method includes: forming one or more photoelectric sensors 8 and a switching thin film transistor 9 connected to the photoelectric sensor 8 on a side of the light-emitting units away from the base substrate 1; forming one or more collimating structures 13 on a light incident side of the photoelectric sensors 8. Specifically, the orthographic projection of the photoelectric sensor 8 on the base substrate 1 is located within a gap between adjacent light-emitting units.

In this embodiment, as shown in FIG. 4, a collimating structure 13 is provided on the light incident side of the photoelectric sensor 8. The external light enters the photoelectric sensor 8 after passing through the collimating structure 13, and by providing the collimating structure 13 on the light incident side, each photoelectric sensor 8 can only detect the light information directly in front of it without being disturbed by the nearby light. As a result, a relatively clear image can be captured by the photoelectric sensor array, so as to improve the photographic quality, and the solution of the present embodiment has a lower implementation cost and is easier to achieve mass production.

As shown in FIGS. 1 and 2, the collimating structure 13 for example includes a light-shielding pattern and a micro-aperture 14 provided in the light-shielding pattern, the micro-aperture 14 being a long and straight aperture, the orthographic projection of the micro-aperture 14 on the base substrate 1 being located within the orthographic projection of the photoelectric sensor 8 on the base substrate 1. Accordingly, through the micro-aperture 14, the photoelectric sensor 8 will only detect light information directly in front of it and will not be disturbed by nearby light.

In this embodiment, each collimating structure 13 may include one micro-aperture 14 or a plurality of micro-apertures 14. When the collimating structure 13 includes a plurality of micro-apertures 14, the orthographic projections of the plurality of micro-apertures 14 on the base substrate 1 are all located within the orthographic projections of the corresponding photoelectric sensors 8 on the base substrate 1, so as to ensure that the light transmitted by the micro-apertures 14 is not transmitted to other areas.

In order to avoid the influence of the light-shielding pattern on the display of the display panel 100, the collimating structure 13 is arranged between adjacent pixel areas so as not to block the light emitted from the pixel areas.

In some embodiments, the manufacturing method for example, further includes: forming a black matrix between the light-emitting units and the photoelectric sensors. And the orthographic projection of the photoelectric sensor on the base substrate is located within an orthographic projection of the black matrix on the base substrate.

When the display panel 100 is operated, the light-emitting unit emits light, and if light of the light-emitting unit is received by the photoelectric sensor 8, the operation of the photoelectric sensor is disturbed, affecting the imaging quality of the photoelectric sensor 8. In order to ensure the imaging quality, the present embodiment provides a black matrix 3 between the light-emitting unit and the photoelectric sensor 8, the black matrix 3 being able to block the light emitted by the light-emitting units, from interfering with the imaging of the photoelectric sensors 8. As shown in FIGS. 1 and 2, the light-emitting display of the display panel 100 and the ambient light detection of the photoelectric sensors 8 do not interfere with each other.

In this embodiment, the black matrix 3 can be formed on the display substrate through a special patterning process, and the insulating film layer of the display substrate can also be made of an opaque material, and the opaque insulating film layer of the display substrate can be multiplexed into the black matrix 3.

In some embodiments, the manufacturing method for example, further includes: forming a pixel definition layer using an opaque material on the base substrate 1. And the light-emitting unit is located within a pixel region defined by the pixel definition layer, and the orthographic projection of the photoelectric sensor on the base substrate is located in an orthographic projection of the pixel definition layer on the base substrate. In this way, the photoelectric sensor 8 is arranged between the adjacent pixel areas so as to be offset from the pixel areas, whereby the aperture ratio of the display panel 100 can be not affected.

The pixel definition layer can be made of a light-transmitting material or an opaque material, and if the pixel definition layer is made of an opaque material, the pixel definition layer can be multiplexed into a black matrix 3. Thus, it is not necessary to fabricate the black matrix 3 on the display substrate through a special patterning process, and the structure and the manufacturing process of the display substrate can be simplified.

In some embodiments, the manufacturing method for example, further includes: forming a color filter layer 11 on the side of the collimating structure 13 away from the photoelectric sensor 8, so that imaging of a color image can be achieved. The color filter layer 11 and the photoelectric sensor 8 can both be provided on the display substrate; they may also be provided on the opposite substrate of the display substrate, such as on the encapsulation cover plate. In addition, it is also possible that the color filter layer 11 is provided on the encapsulation cover plate, and the photoelectric sensor 8 is provided on the display substrate.

The color filter layer 11 includes a plurality of filtering units of different colors, and as shown in FIG. 4, the color filter layer 11 may include a first filtering unit 161, a second filtering unit 162, and a third filtering unit 163.

It should be noted that the various embodiments described herein are described in a progressive manner with reference to the same or similar parts throughout the various embodiments, with each embodiment focusing on differences from the other embodiments. In particular, the embodiments are described more simply because they are substantially similar to the product embodiments, to which reference is now made.

Unless defined otherwise, technical or scientific terms used in this disclosure shall have the ordinary meaning as understood by one of ordinary skill in the art to which this disclosure belongs. As used in this disclosure, the terms “first” , “second” and the like do not denote any order, quantity, or importance, but rather are used to distinguish one element from another. The word “include/comprise” or “contain” or the like, means that the element or object preceded by the word is inclusive of the element or object and its equivalents listed after the word , and does not exclude other elements or objects. Similar terms such as “connect” or “join” are not limited to physical or mechanical connections, but may include electrical connections, whether direct or indirect. “Upper”, “lower”, “left”, “right” and the like are used merely to denote relative positional relationships, which may change accordingly when the absolute position of the subject being described changes.

It can be understood that when an element such as a layer, film, region or substrate is referred to as being “upper” or “lower” located on the other element, it can be “directly upper or lower” located on the other element or intervening elements may be present.

In the description of the embodiments above, particular features, structures, materials, or characteristics may be combined in any suitable manner in any one or more embodiments or examples.

The above embodiments are merely specific implementations of the present disclosure, but the scope of protection of the present disclosure is not limited thereto, and any modification and substitution being apparent to those skilled in the art without departing from the technical scope of the present disclosure shall be covered by the scope of protection of the present disclosure. Accordingly, the scope of protection of the present disclosure is as set forth in the claims.

What is claimed is:

1. A display panel comprising:
a display substrate, wherein the display substrate comprises a base substrate, and one or more thin film transistor arrays and one or more light-emitting units located on the base substrate;
one or more photoelectric sensors located on a side of the light-emitting units away from the base substrate;
one or more switching thin film transistors connected to the photoelectric sensors; and
one or more collimating structures provided on a light incident side of the photoelectric sensors,
wherein an orthographic projection of the photoelectric sensor on the base substrate is located within a gap between adjacent light-emitting units.

2. The display panel according to claim 1, further comprising:
a black matrix located between the light-emitting units and the photoelectric sensors, wherein the orthographic projection of the photoelectric sensor on the base substrate is located within an orthographic projection of the black matrix on the base substrate.

3. The display panel according to claim 1, further comprising:
a pixel definition layer located on the base substrate, wherein the light-emitting unit is located in a pixel region defined by the pixel definition layer, the pixel definition layer is made of an opaque material, and the orthographic projection of the photoelectric sensor on the base substrate is located within an orthographic projection of the pixel definition layer on the base substrate.

4. The display panel according to claim 1, further comprising:
a color filter layer located on a side of the collimating structure away from the photoelectric sensors.

5. The display panel according to claim 1, wherein the collimating structure comprises:
a light-shielding pattern and a micro-aperture located within the light-shielding pattern, wherein an orthographic projection of the micro-aperture on the base substrate is located within the orthographic projection of the photoelectric sensor on the base substrate.

6. The display panel according to claim 1, wherein the photoelectric sensors correspond to sub-pixels of the display panel on a one-to-one basis; or each photoelectric sensor corresponds to a plurality of the sub-pixels.

7. The display panel according to claim 1, further comprising:
an encapsulation layer covering the light-emitting unit, wherein the photoelectric sensor is provided on a side surface of the encapsulation layer away from the light-emitting unit.

8. The display panel according to claim 1, further comprising:
an encapsulation cover plate arranged opposite to the display substrate, wherein the photoelectric sensor is provided on a side of the encapsulation cover plate facing the display substrate.

9. A display device comprising a display panel,
the display panel comprising:
a display substrate, wherein the display substrate comprises a base substrate, and one or more thin film transistor arrays and one or more light-emitting units located on the base substrate;
one or more photoelectric sensors located on a side of the light-emitting units away from the base substrate;
one or more switching thin film transistors connected to the photoelectric sensors; and
one or more collimating structures provided on a light incident side of the photoelectric sensors,
wherein an orthographic projection of the photoelectric sensor on the base substrate is located within a gap between adjacent light-emitting units.

10. The display device according to claim 9, wherein the display panel further comprises:
a black matrix located between the light-emitting units and the photoelectric sensors, wherein the orthographic projection of the photoelectric sensor on the base substrate is located within an orthographic projection of the black matrix on the base substrate.

11. The display device according to claim 9, wherein the display panel further comprises:
a pixel definition layer located on the base substrate, wherein the light-emitting unit is located in a pixel region defined by the pixel definition layer, the pixel definition layer is made of an opaque material, and the orthographic projection of the photoelectric sensor on the base substrate is located within an orthographic projection of the pixel definition layer on the base substrate.

12. The display device according to claim 9, wherein the display panel further comprises:
a color filter layer located on a side of the collimating structure away from the photoelectric sensors.

13. The display device according to claim 9, wherein the collimating structure comprises:
a light-shielding pattern and a micro-aperture located within the light-shielding pattern, wherein an orthographic projection of the micro-aperture on the base substrate is located within the orthographic projection of the photoelectric sensor on the base substrate.

14. The display device according to claim 9, wherein the photoelectric sensors correspond to sub-pixels of the display panel on a one-to-one basis; or
each photoelectric sensor corresponds to a plurality of the sub-pixels.

15. The display device according to claim 9, wherein the display panel further comprises:
an encapsulation layer covering the light-emitting unit, wherein the photoelectric sensor is provided on a side surface of the encapsulation layer away from the light-emitting unit.

16. The display device according to claim 9, wherein the display panel further comprises:
an encapsulation cover plate arranged opposite to the display substrate, wherein the photoelectric sensor is provided on a side of the encapsulation cover plate facing the display substrate.

17. A method for manufacturing a display panel, wherein the display panel comprises a display substrate, the display substrate comprises one or more thin film transistor arrays and one or more light-emitting units which are located on a base substrate, and
the method comprising:
forming one or more photoelectric sensors and one or more switching thin film transistors connected to the photoelectric sensors on a side of the light-emitting unit away from the base substrate; and
forming one or more collimating structures on a light incident side of the photoelectric sensors;
wherein an orthographic projection of the photoelectric sensor on the base substrate is located within a gap between adjacent light-emitting units.

18. The method according to claim 17, further comprising:
forming a black matrix between the light-emitting units and the photoelectric sensors, wherein the orthographic projection of the photoelectric sensor on the base substrate is located within an orthographic projection of the black matrix on the base substrate.

19. The method according to claim 17, further comprising:
forming a pixel definition layer using an opaque material on the base substrate, wherein the light-emitting unit is located within a pixel region defined by the pixel definition layer, and the orthographic projection of the photoelectric sensor on the base substrate is located in an orthographic projection of the pixel definition layer on the base substrate.

20. The method according to claim 17, further comprising:
forming a color filter layer on a side of the collimating structure away from the photoelectric sensor.
